(19) United States
(12) Patent Application Publication
(10) Pub. No.: US 2019/0037733 A1
(43) Pub. Date: Jan. 31, 2019

(54) SERVER-DEVICE CARRIERS AND SERVER-DEVICE-CARRIER COVERS

(71) Applicant: Facebook, Inc., Menlo Park, CA (US)

(72) Inventor: Jon Brian Ehlen, Menlo Park, CA (US)

(21) Appl. No.: 15/665,286

(22) Filed: Jul. 31, 2017

(51) Int. Cl. H05K 7/20; H05K 5/02; H01L 21/48

(52) U.S. Cl. CPC H05K 7/20836; H01L 21/4803; H05K 5/0213

(57) ABSTRACT

A server-device carrier may include a carrier body having (1) a device mounting base, (2) a side wall extending from the device mounting base, and (3) a magnetic mounting member. The server-device carrier may also include a carrier cover having (1) an upper wall abutting an upper portion of the carrier body, (2) a side wall abutting at least a portion of the side wall of the carrier body, with the side wall of the carrier cover extending from the upper wall of the carrier cover toward the device mounting base of the carrier body, and (3) a magnetic coupling member that is magnetically coupled to the magnetic mounting member of the carrier body. The magnetic coupling member may be disposed in the upper wall or the side wall of the carrier cover. Various other apparatuses, systems, and methods are also disclosed.

### BACKGROUND

As data centers grow to meet demands for computational resources, a data center's ability to provide large-scale computation becomes increasingly important. One result of large-scale computation is heat waste generated by many computing devices operating in the same space (e.g., computing devices resting within server racks of data centers). If this heat waste is not effectively managed, the heat waste may interfere with the operation of the computing devices. Traditional data centers employ various cooling systems to manage heat waste. Such cooling systems may impose significant operating costs in the form of energy consumption, as well as costs for acquisition and maintenance. Conventional device carriers housed within server racks are typically designed to allow cooling air to flow over electronic computing components mounted to the device carriers. However, inefficient flow of cooling air through the device carriers may raise overall cooling costs and may limit device capabilities due to potential overheating of the computing components.

### SUMMARY

As will be described in greater detail below, the instant disclosure generally relates to server-device carriers, carrier covers, and methods for coupling carrier covers to carrier bodies of server-device carriers. In one example, a server-device-carrier cover may include (1) an upper wall dimensioned to abut an upper portion of a carrier body of a server-device carrier, (2) a side wall dimensioned to abut a side portion of the carrier body, with the side wall extending from the upper wall in a direction normal to the upper wall, and (3) a magnetic coupling member for magnetically coupling the server-device-carrier cover to the carrier body. The magnetic coupling member may be disposed in the upper wall or the side wall.

In some embodiments, the magnetic coupling member may be disposed adjacent to a periphery of the upper wall. In at least one example, the magnetic coupling member may be disposed in the upper wall adjacent to a junction between the upper wall and the side wall. In this example, the side wall may include a guide member aligned with the magnetic coupling member for guiding the magnetic coupling member into abutment with a corresponding magnetic mounting member of the carrier body, with the guide member projecting inward from an inner surface of the side wall. The guide member may be dimensioned to fit within a corresponding guide recess defined in a side wall of the carrier body.

In at least one embodiment, the server-device-carrier cover may include a plurality of magnetic coupling members for magnetically coupling the server-device-carrier cover to the carrier body, with the plurality of magnetic coupling members including the magnetic coupling member. Each of the plurality of magnetic coupling members may be disposed in the upper wall and/or the side wall. In this example, a first magnetic coupling member of the plurality of magnetic coupling members may be disposed adjacent to a peripheral portion of the upper wall at a junction between the upper wall and the side wall, and a second magnetic coupling member of the plurality of magnetic coupling members may be disposed adjacent to another peripheral portion of the upper wall.

According to some embodiments, the magnetic coupling member may be disposed in a coupling-member recess defined in the upper wall and/or the side wall. In at least one example, the magnetic coupling member may be disposed in a corner region of the upper wall. The server-device-carrier cover may include an opposite side wall that extends from a peripheral portion of the upper wall located opposite the side wall. In this example, the opposite side wall may include a central wall extension that extends away from a wider main portion of the opposite side wall in the direction normal to the upper wall.

A corresponding server-device carrier may include a carrier body having (1) a device mounting base, (2) a side wall extending from the device mounting base, and (3) a magnetic mounting member. The server-device carrier may also include a carrier cover having (1) an upper wall abutting an upper portion of the carrier body, (2) a side wall abutting at least a portion of the side wall of the carrier body, with the side wall of the carrier cover extending from the upper wall of the carrier cover toward the device mounting base of the carrier body, and (3) a magnetic coupling member that is magnetically coupled to the magnetic mounting member of the carrier body. The magnetic coupling member may be disposed in the upper wall or the side wall of the carrier cover.

According to at least one embodiment, the side wall of the carrier body may define a guide recess and the side wall of the carrier cover may include a guide member that projects from an inner surface of the side wall of the carrier cover into the guide recess defined by the side wall of the carrier body. In this example, the magnetic mounting member of the carrier body may be disposed between the magnetic coupling member of the carrier cover and the guide member of the carrier cover. In some examples, the magnetic mounting member of the carrier body may be disposed in an upper portion of the side wall of the carrier body.

The carrier body may be configured to receive air flowing in an airflow direction from one end of the device mounting base to an opposite end of the device mounting base and at least a portion of the carrier cover may be configured to direct the air through the carrier body. In this example, the upper wall of the carrier cover may define a recess that extends longitudinally in the airflow direction and a portion of the upper wall of the carrier cover defining the recess may include an air-guide protrusion that protrudes from an inner surface of the upper wall of the carrier cover toward the device mounting base of the carrier body.

A corresponding method may include (1) orienting a carrier cover over a carrier body of a server-device carrier and (2) positioning the carrier cover on the carrier body. The carrier cover may be positioned on the carrier body such that (1) an upper wall of the carrier cover abuts an upper portion of the carrier body, (2) a side wall of the carrier cover abuts at least a portion of a side wall of the carrier body, with the side wall of the carrier cover extending from the upper wall of the carrier cover toward a device mounting base of the carrier body, and (3) a magnetic coupling member of the carrier cover is magnetically coupled to a magnetic mounting member of the carrier body. The magnetic coupling member may be disposed in the upper wall or the side wall of the carrier cover.

In some embodiments, positioning the carrier cover on the carrier body may include positioning a guide member that projects from an inner surface of the side wall of the carrier cover within a guide recess defined by the side wall of the carrier body such that the magnetic mounting member of the carrier body is disposed between the magnetic coupling member of the carrier cover and the guide member of the carrier cover.

Features from any of the above-mentioned embodiments may be used in combination with one another in accordance with the general principles described herein. These and other embodiments, features, and advantages will be more fully understood upon reading the following detailed description in conjunction with the accompanying drawings and claims.

### BRIEF DESCRIPTION OF THE DRAWINGS

The accompanying drawings illustrate a number of exemplary embodiments and are a part of the specification. Together with the following description, these drawings demonstrate and explain various principles of the instant disclosure.

FIG. 1 is a perspective view of an exemplary server-device carrier.

FIG. 2 is a perspective view of an exemplary carrier cover of a server-device carrier.

FIGS. 3A and 3B are cross-sectional views of an exemplary carrier cover of a server-device carrier.

FIG. 4 is a perspective view of an exemplary carrier body of a server-device carrier.

FIG. 5 is a perspective view of portion of an exemplary carrier cover and carrier body of a server-device carrier.

FIG. 6 is a perspective view of a portion of an exemplary server-system sled that holds a plurality of server-device carriers.

FIG. 7 is a flow diagram of an exemplary method for coupling a carrier cover to a carrier body of a server-device carrier.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the instant disclosure covers all modifications, equivalents, and alternatives falling within the scope of the appended claims.

### DETAILED DESCRIPTION OF EXEMPLARY EMBODIMENTS

The present disclosure describes various server-device carriers, carrier covers, and methods for coupling carrier covers to carrier bodies of server-device carriers. As will be explained in greater detail below, embodiments of the instant disclosure may include server-device carriers having carrier covers that mount to corresponding carrier bodies to direct the flow of cooling air over components mounted within the server-device carriers so as to increase the cooling efficiency of the available cooling air. Magnetic coupling mechanisms may enable the carrier covers to be quickly and easily mounted and coupled to the carrier bodies by a user. The carrier covers may also be readily removed from the carrier bodies as needed. In some examples, the carrier covers may include guide members that may be disposed within corresponding guide recesses defined in the carrier bodies to facilitate positioning and attachment of the carrier covers to the carrier bodies. Accordingly, cooling efficiency for server systems utilizing the disclosed server-device carriers may be improved, reducing costs and allowing for increased device performance. Additionally, device failures and down time due to excessive heat generation may be avoided.

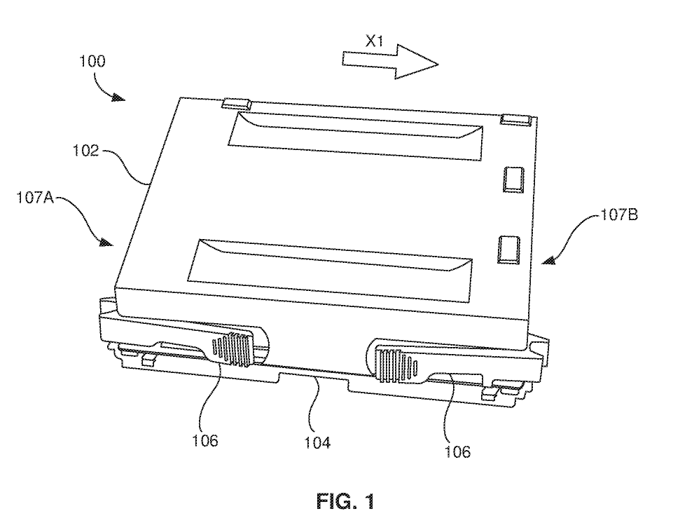

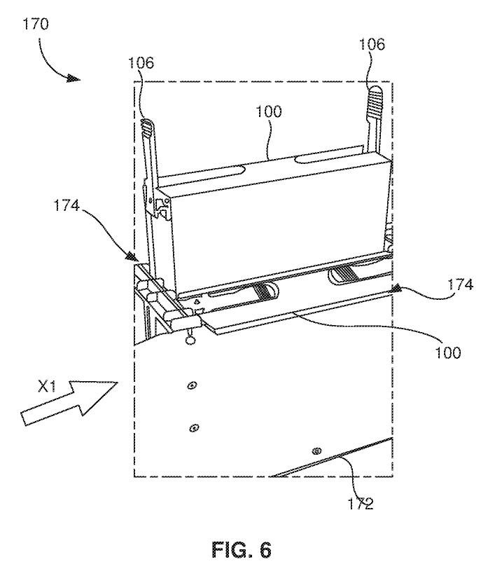

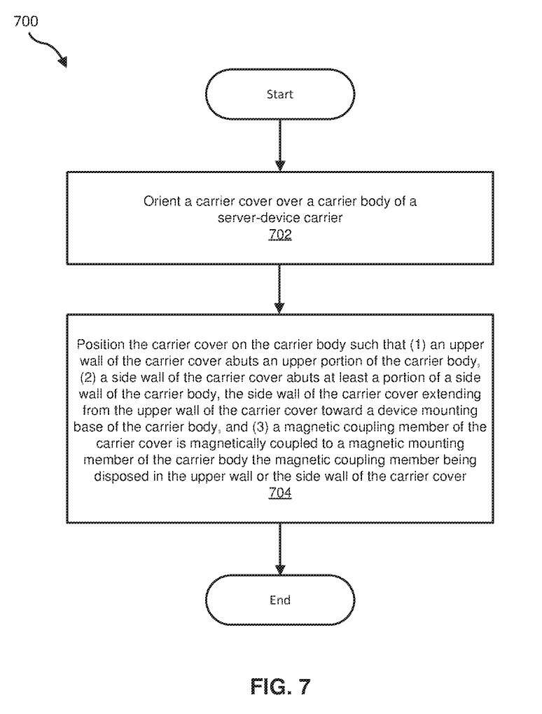

The following will provide, with reference to FIGS. 1-5, examples of server-device carriers. In addition, the discussion corresponding to FIG. 6 will provide examples of server-system sleds for holding a plurality of server-device carriers. Finally, the discussion corresponding to FIG. 7 will provide examples of methods for coupling carrier covers to carrier bodies of server-device carriers.

FIG. 1 shows a server-device carrier 100 that housing electronic computing components for utilization in a server system. As shown in this figure, server-device carrier 100 may include a carrier cover 102 coupled to a carrier body 104. Server-device carrier 100 may also include at least one ejector lever 106 that may be used to load and secure server-device carrier 100 within a corresponding location, such as a carrier slot, in a modular server platform as will be described in greater detail below (see, e.g., FIG. 6). For example, as shown in FIG. 1, server-device carrier 100 may include two ejector levers 106. Carrier cover 102 and carrier body 104 may together form an air passage for directing cooling air through server-device carrier 100 so as to pass the cooling air over electronic components housed within server-device carrier 100. In some embodiments, ejector levers 106 may also define a portion of the air passage when ejector levers 106 are disposed in a closed position as shown in FIG. 1. Server-device carrier 100 may be open at an inlet side 107A and an outlet side 107B of server-device carrier 100 to permit entry and evacuation of cooling air. Server-device carrier 100 may be enclosed or substantially enclosed around top, bottom, and side portions of server-device carrier 100 extending between inlet side 107A and outlet side 107B. Accordingly, cooling air flowing into server-device carrier 100 may flow through an interior of server-device carrier 100 in airflow direction X1 from inlet side 107A to outlet side 107B.

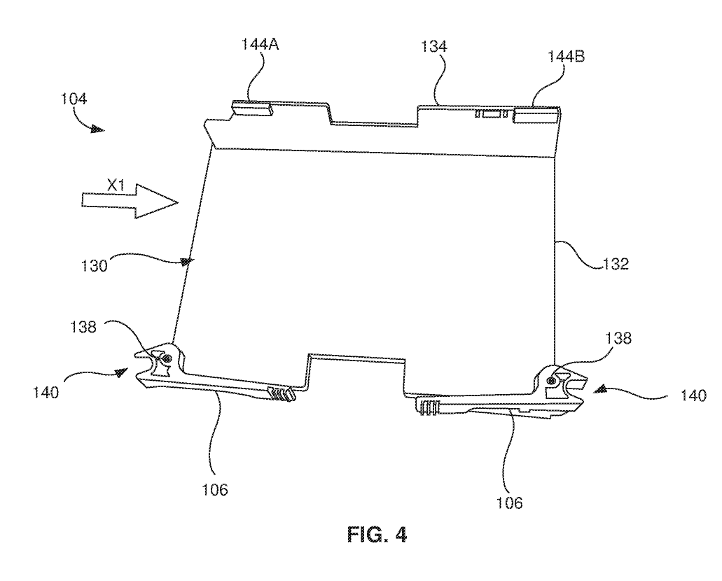

Server-device carrier 100, which includes carrier cover 102, may more efficiently and effectively cool electronic components housed within server-device carrier 100 in comparison to conventional server-device carriers that do not include a cover. For example, inner surface portions of carrier cover 102 may direct a greater portion of available cooling air over the electronic components, which may be coupled to carrier body 104 (see, e.g., FIG. 4). Carrier cover 102 may, for example, enclose a reduce airflow space in conjunction with carrier body 104 so that more of the cooling air directed to server-device carrier 100 passes through the enclosed in server-device carrier 100 in closer proximity to the electronic components than conventional server-device carriers. Accordingly, the cooling air may more effectively cool the electronic components through convective heat transfer. As will be described in greater detail below, carrier cover 102 and carrier body 104 may include one or more additional features to further increase the cooling effectiveness of cooling air passing through server-device carrier 100.

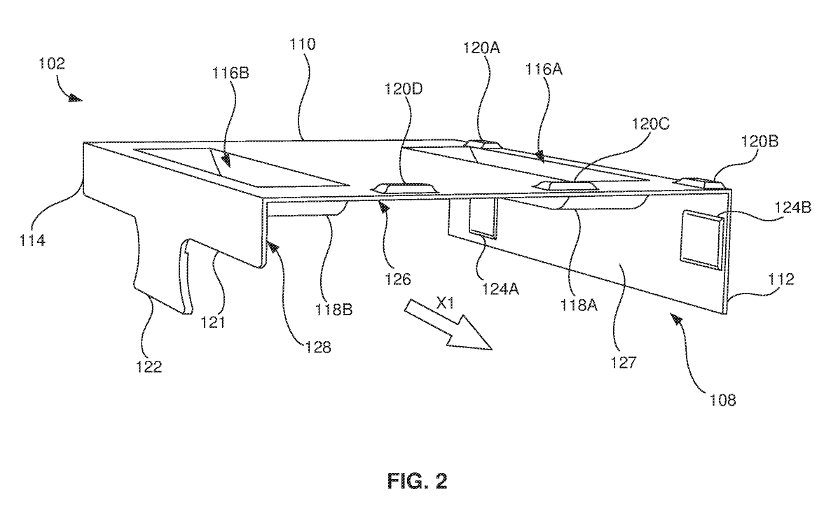

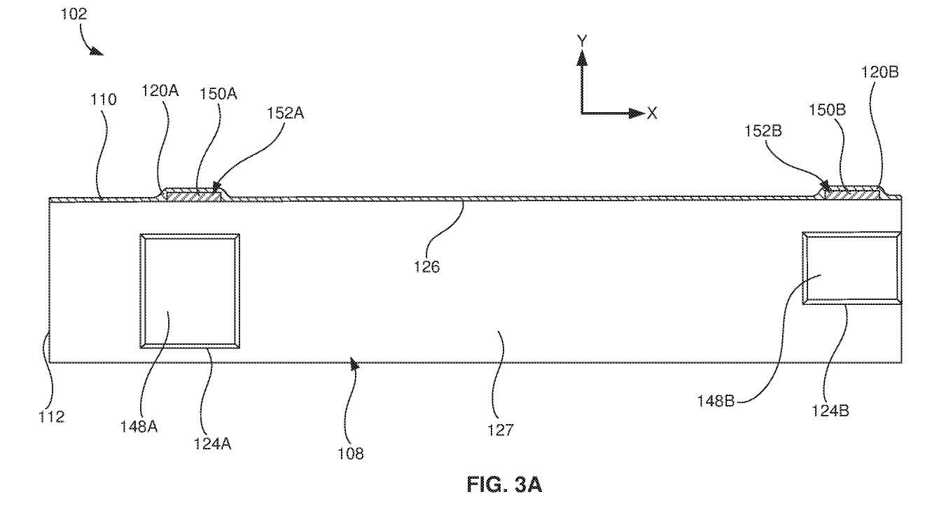

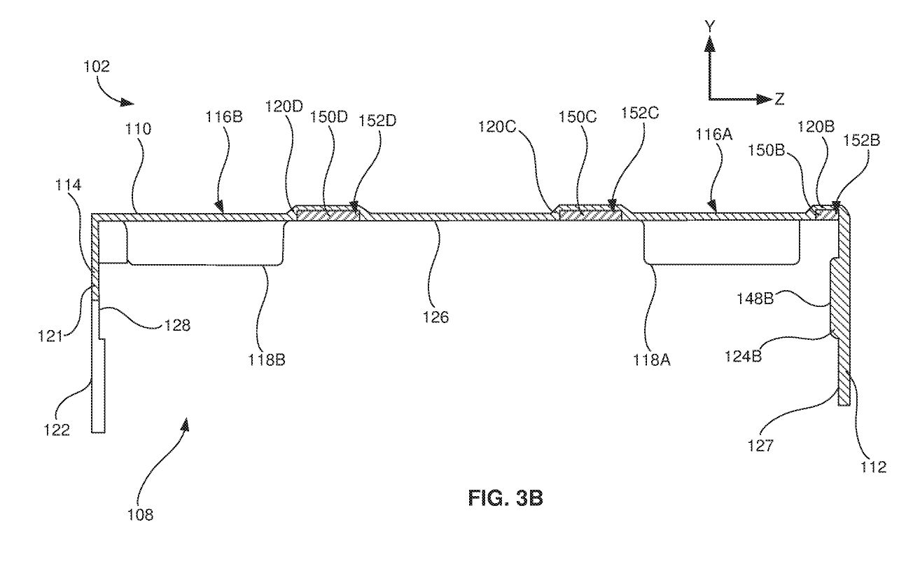

FIGS. 2-3B show carrier cover 102 of server-device carrier 100. Carrier cover 102 may be dimensioned to surround and/or abut at least a portion of carrier body 104, including upper and/or side portions of carrier body 104. As shown in FIG. 2, carrier cover 102 may include an upper wall 110, a first side wall 112 extending from a peripheral portion of upper wall 110, and a second side wall 114 extending from an opposite peripheral portion of upper wall 110. In at least one example, first side wall 112 and/or second side wall 114 may extend from upper wall 110 in a direction normal or substantially normal to upper wall 110. An inner surface 126 of upper wall 110, an inner surface 127 of first side wall 112, and an inner surface 128 of second side wall 114 may together surround a cover interior 108 in which at least a portion of carrier body 104 is disposed when carrier cover 102 is coupled to carrier body 104.

In some embodiments, upper wall 110 of carrier cover 102 may define at least one recess. For example, upper wall 110 may define a first upper-wall recess 116A and a second upper-wall recess 116B. According to at least one example, first upper-wall recess 116A and/or second upper-wall recess 116B may be utilized by a user or machine to grasp carrier cover 102 for purposes of coupling carrier cover 102 to carrier body 104 and/or removing carrier cover 102 from carrier body 104. As shown in FIG. 2, at least a portion of upper wall 110 defining first upper-wall recess 116A and/or second upper-wall recess 116B may protrude inward from a main portion of upper wall 110 toward cover interior 108. For example, carrier cover 102 may include a first air-guide protrusion 118A defining first upper-wall recess 116A and a second air-guide protrusion 118B defining to second upper-wall recess 116B. As shown in FIG. 2, first air-guide protrusion 118A and second air-guide protrusion 118B may each protrude inward from inner surface 126 of upper wall 110 and may each extend longitudinally along upper wall 110 in airflow direction X1. First air-guide protrusion 118A and/or second air-guide protrusion 118B may increase the cooling efficiency of cooling air flowing through server-device carrier 100 by directing the cooling air toward various electronic computing components mounted to carrier body 104.

According to at least one embodiment, second side wall 114 may include a central wall extension 122 that extends, in a direction normal to upper wall 110, away from a wider main wall portion 121 of second side wall 114. Central wall extension 122 may be disposed between ejector levers 106 when carrier cover 102 is coupled to carrier body 104 (see, e.g., FIG. 1). Accordingly, central wall extension 122 may at least partially cover and enclose a space between ejector levers 106 of carrier body 104. When carrier cover 102 is mounted to carrier body 104 and ejector levers 106 are in the closed position shown in FIG. 1, central wall extension 122 and ejector levers 106 may together enclose or substantially enclose a side of carrier body 104 to facilitate flow of cooling air over electronic components of carrier body 104. In some examples, central wall extension 122 may also include a coupling member, such as a magnetic coupling member and/or mechanical fastener, that couples central wall extension 122 to an adjacent portion of carrier body 104 so as to more securely couple carrier cover 102 to carrier body 104.

Carrier cover 102 may also include at least one magnetic coupling portion in any location suitable for coupling carrier cover 102 to carrier body 104. For example, as shown in FIGS. 2-3B, carrier cover 102 may include a first magnetic coupling portion 120A, a second magnetic coupling portion 120B, a third magnetic coupling portion 120C, and a fourth magnetic coupling portion 120D disposed at different locations of upper wall 110 of carrier cover 102. First magnetic coupling portion 120A, second magnetic coupling portion 120B, third magnetic coupling portion 120C, and fourth magnetic coupling portion 120D may each include a magnetic coupling member that is configured to magnetically couple with a corresponding magnetic mounting member of carrier body 104 so as to secure carrier cover 102 to carrier body 104, as will be described in greater detail below. Additionally or alternatively, second side wall 114 and/or first side wall 112 may, for example, include one or more magnetic coupling portions for magnetically coupling with corresponding portions of carrier body 104. In some examples, first magnetic coupling portion 120A, second magnetic coupling portion 120B, third magnetic coupling portion 120C, and/or fourth magnetic coupling portion 120D may be disposed in upper wall 110 adjacent to a periphery of upper wall 110. For example, as shown in FIG. 2, first magnetic coupling portion 120A and second magnetic coupling portion 120B may be disposed adjacent to a peripheral portion of upper wall 110 intersecting first side wall 112, with second magnetic coupling portion 120B being disposed in a corner region of upper wall 110. Additionally, third magnetic coupling portion 120C and fourth magnetic coupling portion 120D may be disposed adjacent to another peripheral portion of upper wall 110, such as a peripheral portion of upper wall 110 extending between first side wall 112 and second side wall 114 at an outlet side of carrier cover 102 (see, e.g., outlet side 107B of server-device carrier 100 shown in FIG. 1).

According to some embodiments, carrier cover 102 may also include at least one guide member for positioning carrier cover 102 in a desired orientation with respect to carrier body 104 and/or for securing carrier cover 102 to carrier body 104. For example, first side wall 112 of carrier cover 102 may include a first guide member 124A located near first magnetic coupling portion 120A and a second guide member 124B located near second magnetic coupling portion 120B. First guide member 124A and second guide member 124B may protrude inward from inner surface 127 of first side wall 112 so as to fit within a corresponding guide recess defined in carrier body 104. First guide member 124A and/or second guide member 124B may, for example, guide carrier cover 102 into proper alignment with carrier body 104 such that first magnetic coupling portion 120A and second magnetic coupling portion 120B are brought into abutment with corresponding magnetic mounting portions of carrier body 104.

FIG. 3A is a cross-sectional view of carrier cover 102 showing a cross-section of carrier cover 102 taken along a plane extending parallel to first side wall 112 and passing through first magnetic coupling portion 120A and second magnetic coupling portion 120B shown in FIG. 2. FIG. 3B is a cross-sectional view of carrier cover 102 showing a cross-section of carrier cover 102 taken along plane extending perpendicular to upper wall 110 from first side wall 112 to second side wall 114 and passing through second magnetic coupling portion 120B, third magnetic coupling portion 120C, and fourth magnetic coupling portion 120D shown in FIG. 2. As shown in FIGS. 3A and 3B, first magnetic coupling portion 120A, second magnetic coupling portion 120B, third magnetic coupling portion 120C, and fourth magnetic coupling portion 120D may each respectively include a first magnetic coupling member 150A, a second magnetic coupling member 150B, a third magnetic coupling member 150C, and a fourth magnetic coupling member 150D. In at least one example, each of first magnetic coupling member 150A, second magnetic coupling member 150B, third magnetic coupling member 150C, and fourth magnetic coupling member 150D may be at least partially disposed in a corresponding recess of upper wall 110. For example, first magnetic coupling member 150A may be disposed in a first coupling-member recess 152A defined by first magnetic coupling portion 120A, second magnetic coupling member 150B may be disposed in a second coupling-member recess 152B defined by second magnetic coupling portion 120B, third magnetic coupling member 150C may be disposed in a third coupling-member recess 152C defined by third magnetic coupling portion 120C, and fourth magnetic coupling member 150D may be disposed in a fourth coupling-member recess 152D defined by fourth magnetic coupling portion 120D. Additionally or alternatively, at least one of first magnetic coupling member 150A, second magnetic coupling member 150B, third magnetic coupling member 150C, and fourth magnetic coupling member 150D may be disposed on a surface portion of upper wall 110, such as, for example, inner surface 126 of upper wall 110.

According to some embodiments, first magnetic coupling member 150A, second magnetic coupling member 150B, third magnetic coupling member 150C, and fourth magnetic coupling member 150D may each include a magnetic material. For example, first magnetic coupling member 150A, second magnetic coupling member 150B, third magnetic coupling member 150C, and fourth magnetic coupling member 150D may each include a magnetized material that produces a magnetic field and/or a ferromagnetic material that is attracted to a magnetized material. Each of first magnetic coupling member 150A, second magnetic coupling member 150B, third magnetic coupling member 150C, and fourth magnetic coupling member 150D may be positioned so as to abut a corresponding magnetic mounting member of carrier body 104 when carrier cover 102 is positioned on carrier body 104 as shown in FIG. 1.

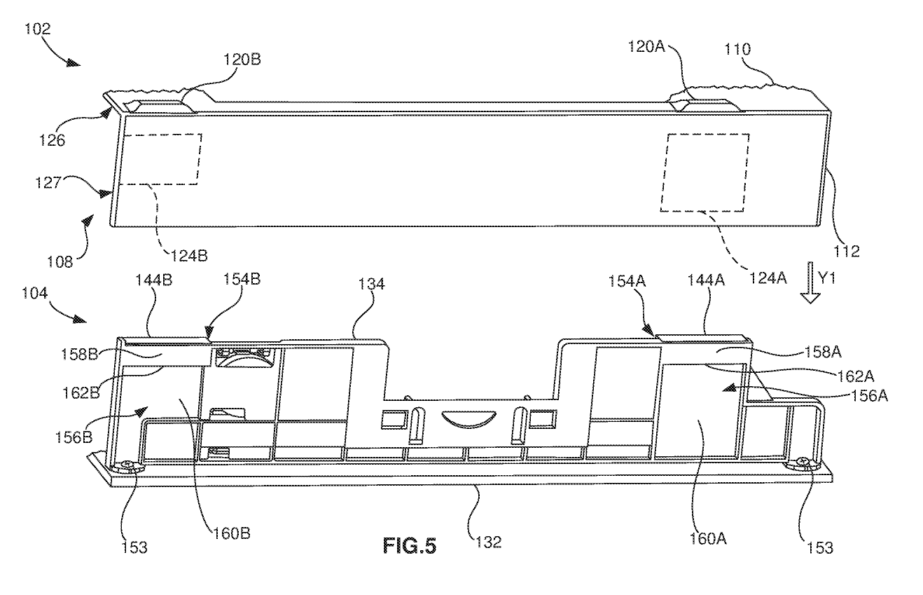

In at least one embodiment, one or more guide members of carrier cover 102 may include a raised portion of first side wall 112 that protrudes inward from inner surface 127 of first side wall 112 to a raised guide surface. For example, as shown in FIGS. 3A and 3B, first guide member 124A may protrude from inner surface 127 to a first guide surface 148A and second guide member 124B may protrude from inner surface 127 to a second guide surface 148B. In some examples, first guide surface 148A and/or second guide surface 148B may be a planar or substantially planar surface that extends, for example, in a direction parallel or substantially parallel to inner surface 127. According to at least one embodiment, at least one magnetic coupling member of carrier cover 102 may be aligned with a corresponding guide member of carrier cover 102. For example, as shown in FIGS. 3A and 3B, first magnetic coupling member 150A may be positioned in alignment with first guide member 124A in the Y dimension shown in FIG. 3A such that first magnetic coupling member 150A is disposed above first guide member 124A. Second magnetic coupling member 150B may also be positioned in alignment with second guide member 124B in the Y dimension such that second magnetic coupling member 150B is disposed above second guide member 124B. As will be shown and described in greater detail below with reference to FIG. 5, such alignment of first guide member 124A and second guide member 124B with first magnetic coupling member 150A and second magnetic coupling member 150B, respectively, may facilitate guidance of carrier cover 102 into proper alignment with carrier body 104 during coupling of carrier cover 102 to carrier body 104. In some embodiments, such a configuration may also enable carrier cover 102 to be more securely coupled to carrier body 104.

FIG. 4 illustrates carrier body 104 of server-device carrier 100. Carrier body 104 may mount various electronic computing device components for a server system. Carrier body 104 may include a device mounting base 132 that mounts the computing device components. In at least one example, carrier body 104 may be customizable to support various electronic computing device components and/or combinations of components. Device mounting base 132 may, for example, include connectors for connecting suitable computing device components to carrier body 104 in a desired configuration. Accordingly, carrier body 104 may include any suitable components in any suitable configuration, without limitation. Electronic computing device components may be communicatively coupled with carrier body 104 by any suitable technology and/or standard (e.g., a peripheral component interconnect (PCI) standard, such as PCI EXPRESS (PCIe) high-speed serial computer expansion bus standard, etc.).

In at least one embodiment, as shown in FIG. 4, carrier body 104 may include, for example, a mounting region 130 on mounting base 132. Any suitable computing device components may be mounted to mounting base 132 in mounting region 130, including, for example, at least one processor, at least one storage module (e.g., one or more hard drives), at least one memory module (e.g., random-access memory (RAM)), at least one graphics module, a power supply, and/or any other suitable computing components. Additionally, at least one heat sink may be coupled to one or more electronic computing device components mounted to mounting base 132.

According to some embodiments, carrier cover 102 may be configured to direct cooling air over components mounted to carrier body 104. For example, as shown in FIGS. 1-3A, first air-guide protrusion 118A and second air-guide protrusion 118B of carrier cover 102 may protrude from inner surface 126 of carrier cover 102 so as to more effectively direct cooling air over electronic components mounted to carrier body 104 when carrier cover 102 is coupled to carrier body 104. In at least one example, when carrier cover 102 is coupled to carrier body 104, first air-guide protrusion 118A and second air-guide protrusion 118B may protrude toward device mounting base 132 of carrier body 104 such that first air-guide protrusion 118A and second air-guide protrusion 118B extend over various components mounted on carrier body 104. Additionally, a central portion of carrier cover 102 between first air-guide protrusion 118A and second air-guide protrusion 118B may accommodate an upper portion of a component, such as a heat sink, between first air-guide protrusion 118A and second air-guide protrusion 118B. Accordingly, when carrier cover 102 is coupled to carrier body 104, portions of carrier cover 102, including first air-guide protrusion 118A and second air-guide protrusion 118B, may be disposed in relatively close proximity to various electronic components of carrier body 104 so as to force a greater proportion of cooling air flowing through server-device carrier 100 directly over the electronic components.

In some embodiments, ejector levers 106 may each be coupled to device mounting base 132 by a corresponding pivot member 138. Ejector levers 106 may be rotated in opposite directions about the corresponding pivot members 138 between the closed position shown in FIG. 4 and an open position in which ejector levers 106 extend outward and away from device mounting base 132 (see, e.g., ejector levers 106 shown in FIG. 6) to facilitate mounting and removal of server-device carrier 100 in a desired server system location. Carrier body 104 may also include a side wall 134 extending from a peripheral portion of device mounting base 132. Side wall 134 may be dimensioned to abut at least a portion of carrier cover 102, such as first side wall 112 shown in FIGS. 2-3B. In some examples, side wall 134 of carrier body 104 may be dimensioned and configured to a couple with first side wall 112 of carrier cover 102, as will be described in greater detail below in reference to FIG. 5. In at least one example, side wall 134 may also mount one or more electronic components of carrier body 104 (batteries, wiring, etc.).

According to at least one embodiment, carrier body 104 may include at least one magnetic mounting member for magnetically coupling with at least one magnetic coupling member of carrier cover 102. For example, carrier body 104 may include a plurality of magnetic mounting members disposed on upper portions of carrier body 104 so as to abut corresponding magnetic coupling members of carrier cover 102. In some embodiments, as shown in FIG. 4, carrier body 104 may include a first magnetic mounting member 144A and a second magnetic mounting member 144B. Each of first magnetic mounting member 144A and second magnetic mounting member 144B may be positioned on upper portions of carrier body 104 so as to respectively contact first magnetic coupling member 150A and second magnetic coupling member 150B of carrier cover 102 shown in FIGS. 2-3B. Accordingly, first magnetic mounting member 144A and second magnetic mounting member 144B of carrier body 104 may be respectively coupled with first magnetic coupling member 150A and second magnetic coupling member 150B of carrier cover 102 when carrier cover 102 is disposed on carrier body 104, thereby coupling and securing carrier cover 102 to carrier body 104 in the manner shown in FIG. 1. First magnetic mounting member 144A and second magnetic mounting member 144B may each include a magnetic material, such as, for example, a magnetized material that produces a magnetic field and/or a ferromagnetic material that is attracted to a magnetized material.

In some embodiments, as shown in FIG. 4, first magnetic mounting member 144A and second magnetic mounting member 144B may be disposed in and/or on upper portions of side wall 134. In at least one example, additional magnetic mounting members may additionally or alternatively be disposed on upper and/or side portions of carrier body 104 and/or on components mounted to carrier body 104. For example, one or more magnetic mounting members may be disposed on one or more portions of carrier body 104 and/or on one or more components (e.g., on an upper portion of a heat sink, etc.) mounted to carrier body 104 in positions corresponding to third magnetic coupling member 150C and/or fourth magnetic coupling member 150D of carrier cover 102 (see, e.g., FIGS. 2 and 3B). Accordingly, carrier cover 102 may be further coupled to carrier body 104 by third magnetic coupling member 150C and/or fourth magnetic coupling member 150D.

FIG. 5 illustrates a portion of carrier cover 102 that includes first side wall 112 positioned over a portion of carrier body 104 that includes side wall 134 prior to coupling carrier cover 102 with carrier body 104. As shown in this figure, side wall 134 may be coupled to device mounting base 132 of carrier body 104 by any suitable fastener or other coupling member. For example, screws 153 may couple side wall 134 to device mounting base 132 at a base portion of side wall 134.

In some embodiments, side wall 134 of carrier body 104 may include one or more features for guiding carrier cover 102 into proper alignment and abutment with carrier body 104 during coupling. For example, as shown in FIG. 5, side wall 134 of carrier body 104 may define a first guide recess 156A and a second guide recess 156B on a side positioned to face first side wall 112 of carrier cover 102. First guide recess 156A may be defined inward from a first side-wall surface 158A to a first guide-recess surface 160A and second guide recess 156B may be defined inward from a second side-wall surface 158B to a second guide-recess surface 160B. A portion of side wall 134 defining an upper side of first guide recess 156A may form a first shoulder 162A and a portion of side wall 134 defining an upper side of second guide recess 156B may form a second shoulder 162B. First magnetic mounting member 144A may be located in an upper portion of side wall 134 such as a first mounting-member recess 154A defined by side wall 134. Additionally, second magnetic mounting member 144B may be located in an upper portion of side wall 134 such as a second mounting-member recess 154B defined by side wall 134. Accordingly, as illustrated in FIG. 5, first magnetic mounting member 144A may be disposed over first guide recess 156A and second magnetic mounting member 144B may be disposed over second guide recess 156B.

When carrier cover 102 is lowered in direction Y1 from the position shown in FIG. 5 toward carrier body 104, first guide member 124A and second guide member 124B of carrier cover 102 may be respectively aligned with first guide recess 156A and second guide recess 156B of carrier body 104. As carrier cover 102 is lowered in direction Y1, first guide member 124A may be guided along first guide recess 156A and second guide member 124B may be guided along second guide recess 156B until first guide member 124A and second guide member 124B are each disposed respectively in first guide recess 156A and second guide recess 156B. In this position, first magnetic coupling member 150A and second magnetic coupling member 150B of carrier cover 102 (see, e.g., FIGS. 3A and 3B) may be respectively positioned abutting first magnetic mounting member 144A and second magnetic mounting member 144B of carrier body 104. Accordingly, first guide recess 156A and second guide recess 156B of carrier body 104 may respectively guide first guide member 124A and second guide member 124B of carrier cover 102 into a coupling position such that first magnetic coupling member 150A and second magnetic coupling member 150B of carrier cover 102 are magnetically coupled with first magnetic mounting member 144A and second magnetic mounting member 144B, respectively.

In some embodiments, carrier cover 102 may be further secured to carrier body 104 when first guide member 124A and second guide member 124B of carrier cover 102 are respectively disposed in first guide recess 156A and second guide recess 156B of carrier body 104. For example, first shoulder 162A at the upper side of first guide recess 156A and second shoulder 162B at the upper side of second guide recess 156B may inhibit first guide member 124A and second guide member 124B from being displaced out of first guide recess 156A and second guide recess 156B, respectively. Accordingly, carrier cover 102 may be quickly and securely coupled to carrier body 104 by a user. Additionally, carrier cover 102 may be easily separated and removed from carrier body 104 as needed by, for example, lifting carrier cover 102 away from carrier body 104 in a direction opposite to Y1. In at least one example, first side wall 112 of carrier cover 102 may be angled away from side wall 134 of carrier body 104 to enable first guide member 124A and second guide member 124B of carrier cover 102 to be removed from first guide recess 156A and second guide recess 156B defined in side wall 134.

According to at least one embodiment, when first guide member 124A of carrier cover 102 is positioned within first guide recess 156A defined by side wall 134 of carrier body 104, first magnetic mounting member 144A of carrier body 104 may be disposed between first magnetic coupling member 150A and first guide member 124A of carrier cover 102. Additionally, when second guide member 124B of carrier cover 102 is positioned within second guide recess 156B defined by side wall 134 of carrier body 104, second magnetic mounting member 144B of carrier body 104 may be disposed between second magnetic coupling member 150B and second guide member 124B of carrier cover 102. In some embodiments, carrier body 104 may include at least one guide member and carrier cover 102 may define at least one corresponding guide recess to facilitate positioning and coupling of carrier cover 102 to carrier body 104. For example, side wall 134 of carrier body 104 may include at least one guide member protruding from an outer surface of side wall 134 and first side wall 112 of carrier cover 102 may define at least one corresponding guide recess that is dimensioned to surround at least a portion of the at least one guide member.

FIG. 6 shows a portion of a server-system sled 170 that houses a plurality of server-device carriers 100 that are utilized in a modular multi-node server system. Server-system sled 170 may be configured to be loaded into a server shelf that may house multiple server sleds and that is utilized in a server-rack system. As shown in FIG. 6, server-system sled 170 may include a sled chassis 172 having a plurality of carrier slots 174 that are configured to receive and house server-device carriers 100. For example, each server-device carrier 100 may be inserted into a carrier slot 174 with ejectors levers 106 disposed in an open position facing outward. Once each server-device carrier 100 is inserted into the corresponding carrier slot 174, ejector levers 106 may be rotated toward the closed position facing inward (see, e.g., FIG. 1). Rotating ejector levers 106 of a server-device carrier 100 into the closed position may lock the server-device carrier 100 into the corresponding carrier slot 174. When server-system sled 170 is disposed in a server rack, cooling air may be directed through server-system sled 170, and likewise through each loaded server-device carrier 100, in airflow direction X1.

FIG. 7 is a flow diagram of an exemplary method 700 for coupling a carrier cover to a carrier body of a server-device carrier. The steps shown in FIG. 7 may be performed by an individual and/or by any suitable manual and/or automated apparatus.

At step 702 in FIG. 7, a carrier cover may be oriented over a carrier body of a server-device carrier. For example, carrier cover 102 may be oriented over carrier body 104 of server-device carrier 100 (see, e.g., FIGS. 1 and 5).

At step 704 in FIG. 7, the carrier cover may be positioned on the carrier body such that (1) an upper wall of the carrier cover abuts an upper portion of the carrier body, (2) a side wall of the carrier cover abuts at least a portion of a side wall of the carrier body, with the side wall of the carrier cover extending from the upper wall of the carrier cover toward a device mounting base of the carrier body, and (3) a magnetic coupling member of the carrier cover is magnetically coupled to a magnetic mounting member of the carrier body. The magnetic coupling member may be disposed in the upper wall or the side wall of the carrier cover.

For example, carrier cover 102 may be positioned on carrier body 104 such that upper wall 110 of carrier cover 102 abuts an upper portion of carrier body 104 and first side wall 112 of carrier cover 102 abuts at least a portion of side wall 134 of carrier body 104 (see, e.g., FIGS. 1, 4, and 5). Side wall 134 of carrier cover 102 may extend from upper wall 110 of carrier cover 102 toward device mounting base 132 of the carrier body 104 (see, e.g., FIGS. 2-3B and 5). First magnetic coupling member 150A and/or second magnetic coupling member 150B of carrier cover 102 may be magnetically coupled to corresponding first magnetic mounting member 144A and/or second magnetic mounting member 144B of carrier body 104. First magnetic coupling member 150A and/or second magnetic coupling member 150B may be disposed in upper wall 110 or first side wall 112 of carrier cover 102 (see, e.g., FIGS. 2-5).

In some embodiments, positioning the carrier cover on the carrier body may include positioning a guide member that projects from an inner surface of the side wall of the carrier cover within a guide recess defined by the side wall of the carrier body such that the magnetic mounting member of the carrier body is disposed between the magnetic coupling member of the carrier cover and the guide member of the carrier cover.

For example, first guide member 124A or second guide member 124B, which each project from inner surface 127 of side wall 112 of carrier cover 102, may be positioned within corresponding first guide recess 156A or second guide recess 156B defined by side wall 134 of carrier body 104 such that the first magnetic mounting member 144A or second magnetic mounting member 144B of carrier body 104 is disposed between a corresponding first magnetic coupling member 150A or second magnetic coupling member 150B of carrier cover 102 and a corresponding first guide member 124A or second guide member 124B of carrier cover 102 (see, e.g., FIGS. 2-3B and 5).

As discussed throughout the instant disclosure, the disclosed methods, systems, and devices may provide one or more advantages over traditional server-device carriers and systems. For example, the disclosed server-device carriers may include carrier covers that direct the flow of cooling air over components mounted within the server-device carriers to increase the cooling efficiency of the available cooling air. Accordingly, cooling cost efficiency for server systems may be improved by utilizing the disclosed server-device carriers. Additionally, device failures and down time due to excessive heat generation may be avoided. Magnetic coupling mechanisms may enable the carrier covers to be quickly and easily mounted and coupled to carrier bodies of the server-device carriers by a user or machine. The carrier covers may also be readily removed from the carrier bodies as needed. In some examples, the carrier covers may include guide members that may be disposed within corresponding guide recesses defined in the carrier bodies to facilitate positioning and attachment of the carrier covers to the carrier bodies.

The foregoing description, for purposes of explanation, has been described with reference to specific embodiments and has been provided to enable others skilled in the art to best utilize various aspects of the example embodiments disclosed herein. However, the illustrative discussions above are not intended to be exhaustive or to limit the scope of the claims to the precise forms disclosed. Many modifications and variations are possible in view of the above teachings without departing from the spirit and scope of the instant disclosure. In addition, any disclosure of components contained within other components should be considered exemplary in nature since many other architectures can be implemented to achieve the same functionality. The instant disclosure covers all modifications, equivalents, and alternatives falling within the scope of the appended claims. Features from any of the above-mentioned embodiments may be used in combination with one another in accordance with the general principles described herein. The embodiments were chosen to best explain the principles underlying the claims and their practical applications, to thereby enable others skilled in the art to best use the embodiments with various modifications as are suited to the particular uses contemplated. The embodiments disclosed herein should be considered in all respects illustrative and not restrictive. Reference should be made to the appended claims and their equivalents in determining the scope of the instant disclosure.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

It will also be understood that, although the terms first, second, primary, etc. are, in some instances, used herein to describe various elements, these elements should not be limited by these terms. These terms are used only to distinguish one element from another. For example, a first segment could be termed a second segment, and, similarly, a second segment could be termed a first segment, without departing from the scope of the various described embodiments. The first segment and the second segment are both segments, but they are not the same segment.

The terminology used in the description of the various described embodiments herein is for the purpose of describing particular embodiments only and is not intended to be limiting. As used in the description of the various described embodiments and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “exemplary” is used herein in the sense of “serving as an example, instance, or illustration” and not in the sense of “representing the best of its kind.” Unless otherwise noted, the terms “connected to,” “coupled to,” and “attached to” (and their derivatives), as used in the specification and claims, are to be construed as permitting both direct and indirect (i.e., via other elements or components) connection. Furthermore, two or more elements may be coupled together with an adhesive, a clasp, a latch, a hook, a link, a buckle, a bolt, a screw, a rivet, a snap, a catch, a lock, or any other type of fastening or connecting mechanism.

What is claimed is:

1. A server-device-carrier cover comprising:
an upper wall dimensioned to abut an upper portion of a carrier body of a server-device carrier;
a side wall dimensioned to abut a side portion of the carrier body, the side wall extending from the upper wall in a direction normal to the upper wall; and
a magnetic coupling member for magnetically coupling the server-device-carrier cover to the carrier body, wherein the magnetic coupling member is disposed in the upper wall or the side wall.

2. The server-device-carrier cover of claim 1, wherein the magnetic coupling member is disposed adjacent to a periphery of the upper wall.

3. The server-device-carrier cover of claim 1, wherein the magnetic coupling member is disposed in the upper wall adjacent to a junction between the upper wall and the side wall.

4. The server-device-carrier cover of claim 3, wherein the side wall comprises a guide member aligned with the magnetic coupling member for guiding the magnetic coupling member into abutment with a corresponding magnetic mounting member of the carrier body, the guide member projecting inward from an inner surface of the side wall.

5. The server-device-carrier cover of claim 4, wherein the guide member is dimensioned to fit within a corresponding guide recess defined in a side wall of the carrier body.

6. The server-device-carrier cover of claim 1, further comprising a plurality of magnetic coupling members for magnetically coupling the server-device-carrier cover to the carrier body, the plurality of magnetic coupling members comprising the magnetic coupling member, wherein each of the plurality of magnetic coupling members is disposed in at least one of the upper wall or the side wall.

7. The server-device-carrier cover of claim 6, wherein:
a first magnetic coupling member of the plurality of magnetic coupling members is disposed adjacent to a peripheral portion of the upper wall at a junction between the upper wall and the side wall; and
a second magnetic coupling member of the plurality of magnetic coupling members is disposed adjacent to another peripheral portion of the upper wall.

8. The server-device-carrier cover of claim 1, wherein the magnetic coupling member is disposed in a coupling-member recess defined in the at least one of the upper wall or the side wall.

9. The server-device-carrier cover of claim 1, wherein the magnetic coupling member is disposed in a corner region of the upper wall.

10. The server-device-carrier cover of claim 1, further comprising an opposite side wall that extends from a peripheral portion of the upper wall located opposite the side wall.

11. The server-device-carrier cover of claim 10, wherein the opposite side wall comprises a central wall extension that extends away from a wider main portion of the opposite side wall in the direction normal to the upper wall.

12. A server-device carrier comprising:
a carrier body comprising:
a device mounting base;
a side wall extending from the device mounting base; and
a magnetic mounting member; and
a carrier cover comprising:
an upper wall abutting an upper portion of the carrier body;
a side wall abutting at least a portion of the side wall of the carrier body, the side wall of the carrier cover extending from the upper wall of the carrier cover toward the device mounting base of the carrier body; and
a magnetic coupling member that is magnetically coupled to the magnetic mounting member of the carrier body, wherein the magnetic coupling member is disposed in the upper wall or the side wall of the carrier cover.

13. The server-device carrier of claim 12, wherein:
the side wall of the carrier body defines a guide recess; and
the side wall of the carrier cover comprises a guide member that projects from an inner surface of the side wall of the carrier cover into the guide recess defined by the side wall of the carrier body.

14. The server-device carrier of claim 13, wherein the magnetic mounting member of the carrier body is disposed between the magnetic coupling member of the carrier cover and the guide member of the carrier cover.

15. The server-device carrier of claim 12, wherein the magnetic mounting member of the carrier body is disposed in an upper portion of the side wall of the carrier body.

16. The server-device carrier of claim 12, wherein the carrier cover further comprises an opposite side wall that extends from a peripheral portion of the upper wall located opposite the side wall of the carrier cover.

17. The server-device carrier of claim 12, wherein:
the carrier body is configured to receive air flowing in an airflow direction from one end of the device mounting base to an opposite end of the device mounting base; and
at least a portion of the carrier cover is configured to direct the air through the carrier body.

18. The server-device carrier of claim 17, wherein:
the upper wall of the carrier cover defines a recess that extends longitudinally in the airflow direction; and
a portion of the upper wall of the carrier cover defining the recess comprises an air-guide protrusion that protrudes from an inner surface of the upper wall of the carrier cover toward the device mounting base of the carrier body.

19. A method comprising:
orienting a carrier cover over a carrier body of a server-device carrier; and
positioning the carrier cover on the carrier body such that:
an upper wall of the carrier cover abuts an upper portion of the carrier body;
a side wall of the carrier cover abuts at least a portion of a side wall of the carrier body, the side wall of the carrier cover extending from the upper wall of the carrier cover toward a device mounting base of the carrier body; and
a magnetic coupling member of the carrier cover is magnetically coupled to a magnetic mounting member of the carrier body, wherein the magnetic coupling member is disposed in the upper wall or the side wall of the carrier cover.

20. The method of claim 19, wherein positioning the carrier cover on the carrier body further comprises positioning a guide member that projects from an inner surface of the side wall of the carrier cover within a guide recess defined by the side wall of the carrier body such that the magnetic mounting member of the carrier body is disposed between the magnetic coupling member of the carrier cover and the guide member of the carrier cover.
